(19) United States
(12) Patent Application Publication
(10) Pub. No.: US 2007/0040206 A1
(43) Pub. Date: Feb. 22, 2007

(54) High dielectric material composed of sintered body of rare earth sulfide

(76) Inventors: Shinji Hirai, Hokkaido (JP); Toshiyuki Nishimura, Ibaraki (JP); Yoichiro Uemura, Ibaraki (JP); Shigenori Morita, Osaka (JP); Michihiro Ohta, Hokkaido (JP); Kazumasa Igarashi, Osaka (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(21) Appl. No.: 10/550,625

(22) PCT Filed: Mar. 22, 2004
(86) PCT No.: PCT/JP04/03883

§ 371 Date: Jul. 10, 2006

(30) Foreign Application Priority Data
Mar. 27, 2003 (JP) 2003-086830

(51) Int. Cl. H01L 29/94

(52) U.S. Cl. 257/310

(57) ABSTRACT

A high-dielectric material which is especially useful as a material for a high-capacitance capacitor and which has a high dielectric constant is provided. The high-dielectric material is composed of a sintered body of a rare-earth sulfide, the high-dielectric material having a crystal structure of tetragonal β type, a chemical composition represented by Ln₂S₃ (where Ln represents a rare-earth metal), a frequency domain within the range of 0.5 kHz to 1,000 kHz, and a value of relative dielectric constant of more than 1,000 at room temperature.

### TECHNICAL FIELD

The present invention relates to a high-dielectric material composed of a sintered body of a rare-earth sulfide. The high-dielectric material is especially useful as a material for a high-capacitance capacitor and has a high dielectric constant.

### BACKGROUND ART

Previously, substances having high dielectric constants have been searched and studied. Examples thereof include a perovskite-structure ferroelectric which is referred to as a relaxor and which includes a diffusive phase containing lead (Pb), zinc (Zn), and niobium (Nb) (Non-Patent Documents 1 and 2) and a sintered body which includes semiconductor barium titanate or strontium titanate as a ground material and which has an apparent dielectric constant increased by taking advantage of a very thin insulating boundary layer (Non-Patent Document 3).

Non-Patent Document 1 S. E. Park, M. L. Mulvihill, G. Risch and T. R. Shrout, “The effect of Growth Conditions on the Dielectric Properties of Pb(Zn_{1/3}Nb_{2/3})O₃ Single Crystals”, Jpn. J. Appl. Phys., 36 (1997) pp. 1154-1158 Non-Patent Document 2 “Yuudentaizairyono tokuseito sokutei·hyoka oyobi ouyougijutsu (Properties of dielectric materials and measurement·evaluation and application technologies)”, TECHNICAL INFORMATION INSTITUTE CO., LTD., 2001, p 292

Non-Patent Document 3 M. Fujimoto and W. D. Kingery, “Microstructure of SrTiO₃ Internal Boundary Layer Capacitors During and After Processing and Resultant Electrical properties”, J. Am. Cerm. Soc., 68 (1985) 169-173

### DISCLOSURE OF INVENTION

(Problems to be Solved by the Invention)

With respect to substances having high dielectric constants, research has been conducted on the relaxor in the form of a single crystal, and there are shape and strength problems in an application to capacitors. The dielectric constant has large temperature dependence, and a high dielectric constant is exhibited at a temperature in the vicinity of the ferroelectric transition point. However, a reported value of the dielectric constant is on the order of a few thousand at nearly room temperature.

In the case of a semiconductor capacitor taking advantage of a boundary layer, since the thickness of the boundary layer is very small and the uniformity is poor, a problem occurs in the resistance to the withstand voltage or an electrical shock.

The capacitance F of a disk type capacitor is represented by F∝ε·S/d where a dielectric constant of a dielectric is indicated by ε, the thickness in an electrode direction is indicated by d, and an electrode area is indicated by S. In a monolithic ceramic capacitor, electrodes and dielectrics are laminated alternately to increase S and decrease d, so that a capacitor having large F can be produced.

The dielectric used in the monolithic capacitor is primarily barium titanate having a high dielectric constant. With respect to this substance, as in the relaxor, a high dielectric constant is exhibited at a temperature in the vicinity of the ferroelectric transition point. That temperature of a pure crystal is about 120° C. In order to use the capacitor having a high capacitance at ambient temperature, the transition temperature is reduced by variously processing, for example, other elements are added to this barium titanate. Consequently, problems occur in the temperature stability, the secular change, and the like.

(Means for Solving the Problems)

The inventors of the present invention have reported up to now that lanthanum sulfide based sintered bodies have exhibited excellent thermoelectric properties (refer to the following documents).
\hat{1} S. Hirai et al., “α-La₂S₃ no gouseito netsudentokusei (Synthesis and thermoelectric properties of α-La₂S₃)”, Collected Abstracts of the 1999 (125th) Autumn Meeting of the Japan Inst. Metals, November 1999, p 317
\hat{2} S. Hirai et al., “Rantanoidokei nigenkei ryuukabutsuno gouseito syouketsu (Synthesis and sintering of lanthanoid based binary sulfide)”, Kinzoku (Metal), Vo. 70, No. 8, 2000, pp 629-635
\hat{3} S. Hirai et al., “Taikazairyouya netsudenzairyou toshite kitaisareru Rantanoido nigenkei ryuukabutsu (Lanthanoid based binary sulfide expected as a fire-resistant material and a thermoelectric material)”, Kinzoku (Metal), Vo. 70, No. 11, 2000, pp 960-965
\hat{4} Y. Uemura et al., “Pd o tenkashita La₂S₃ jouatsu syouketsutaino netsudentokusei (Thermoelectric properties of a La₂S₃ atmospheric pressure sintered body including Pd)”, Proceedings of the physical Society of Japan 2001 Autumn Meeting, Vol. 56, No. 2, Part 4, 2001, p 530
\hat{5} Japanese Unexamined Patent Application Publication No. 2001-335367

The lanthanum sulfide is irreversively transformed from an orthorhombic α phase that is a low-temperature stability phase to an electrically insulating material tetragonal β phase, and furthermore, to a semiconductor Th₃P₄ type cubic γ phase. Therefore, in the sintering conducted at a high temperature to produce a dense sintered body having excellent strength, the γ phase predominates and a dielectric property cannot be achieved. On the other hand, when a lanthanum sulfide raw material having an oxygen concentration exceeding 0.9 percent by weight is sintered at a high temperature of 1,500° C., no γ phase appears, and a dense sintered body can be produced while the β phase is left unchanged.

That is, the present invention relates to (1) a high-dielectric material composed of a sintered body of a rare-earth sulfide, the high-dielectric material having a crystal structure of tetragonal β type, a chemical composition represented by Ln₂S₃ (where Ln represents a rare-earth metal), a frequency domain within the range of 0.5 kHz to 1,000 kHz, and a value of relative dielectric constant of more than 1,000 at room temperature.

The present invention relates to (2) the high-dielectric material according to the above-described item (1), characterized in that the rare earth is at least one of lanthanum (La), praseodymium (Pr), cerium (Ce), and neodymium (Nd).

The present invention relates to (3) the high-dielectric material according to the above-described item (1) or (2), characterized in that platinum is added to prevent a crystal structure of β type sesquisulfide from being inverted to γ type at a high temperature.

Furthermore, the present invention relates to (4) a capacitor characterized by including the high-dielectric material according to any one of the above-described item (1) to item (3).

The β-type structure dielectric material of the present invention has a dielectric constant exceeding 100,000, in some cases, exceeding 1,000,000, at room temperature, and a change in the value thereof can be controlled at about one order in a frequency range of 0.5 kHz to 1,000 kHz. The value of tanδ is in between 0 and 2. When the frequency is 1 kHz, the temperature dependence of the dielectric constant of the present dielectric material is increased in accordance with the temperature in the range of about 200 K to about 370 K. However, the increase can be controlled at one order or less.

In the present invention, since the rare-earth sulfide having a high dielectric constant can be provided as a molded body in the shape of a bulk, a high-capacitance capacitor having a desired shape and excellent mechanical strength can be produced. Furthermore, no particular processing, e.g., addition of impurities, is required to produce a dielectric having a high dielectric constant. Therefore, when the dielectric having a high dielectric constant is used in production of a monolithic capacitor, a higher-capacitance, highly stable capacitor can be produced.

### BRIEF DESCRIPTION OF THE DRAWINGS

FIG. 1 is a graph showing the relationship between the applied frequency and the relative dielectric constant of a lanthanum sulfide (La₂S₃) sintered body produced by a plasma sintering method in Example 1. FIG. 2 is a graph showing the relationship between the applied frequency and the relative dielectric constant of a platinum-containing lanthanum sulfide (La₂S₃) sintered body produced by a hot press method in Example 2. FIG. 3 is a graph showing the relationship between the relative dielectric constant at an applied frequency of 1 kHz and the measurement temperature of a platinum-containing lanthanum sulfide (La₂S₃) sintered body produced by the hot press method in Example 2.

### BEST MODE FOR CARRYING OUT THE INVENTION

The present invention relates to the high-dielectric material having the above-described configuration. The material is produced from a rare-earth sulfide (Ln₂S₃) powder as s raw material by an atmospheric sintering method, a hot press method, a plasma sintering method, or the like.

The structure of the sintered body becomes a β-type structure by specifying the oxygen concentration of the rare-earth sulfide raw material to be 0.9 percent by weight or more at a sintering temperature of 1,500° C. or less. Preferably, the rare earth element constituting the rare-earth sulfide is at least one of lanthanum (La), praseodymium (Pr), cerium (Ce), and neodymium (Nd). This is because they have a tetragonal R-type structure which is an electrically insulating material and, thereby, high dielectric constants are exhibited.

In the case where an element is added to the rare-earth sulfide having a β-type structure, some elements allow inversion to the γ type at a low temperature as compared with that of the rare-earth sulfide without addition, and conversely, some elements hinder the inversion until a high temperature is reached. The reason for this is believed to depend on the reactivity with oxygen contained in the β type. However, it is still not certain. Platinum is an element which hinders the inversion to the γ type, and is a useful additive element in the dielectric material of the present invention taking advantage of the β-type structure of the rare-earth sulfide.

For example, the following method is used for producing a sintered body, wherein a rare-earth sulfide raw material powder including platinum is used as a starting material. A platinum powder is mixed into a β-type lanthanoid sesquisulfide powder having a content of oxygen as an impurity of 0.9 percent by mass or more and represented by a compositional formula Ln₂S₃ (where Ln represents at least one selected from the group consisting of La, Ce, Pr, Nd, Sm, Eu, Gd, Tb, Dy, Ho, Er, Tm, Yb, and Lu). After molding or simultaneously with the molding, sintering is conducted at a temperature within the range of 1,300° C. to 1,700° C. Preferably, the platinum powder has an average particle diameter of 50 μm or less and the amount of mixing is 1.5 percent by mass or less.

For the purpose of producing a capacitor by using the above-described dielectric material, it is only essential that molding into the shape of a disk is conducted and the disk is sandwiched between metal electrodes in a vertical direction. The type of the metal and the like serving as the electrode is not specifically limited. For the purpose of producing a higher-capacitance capacitor, a monolithic capacitor is constructed by laminating alternately the electrodes and the dielectric materials.

### EXAMPLE 1

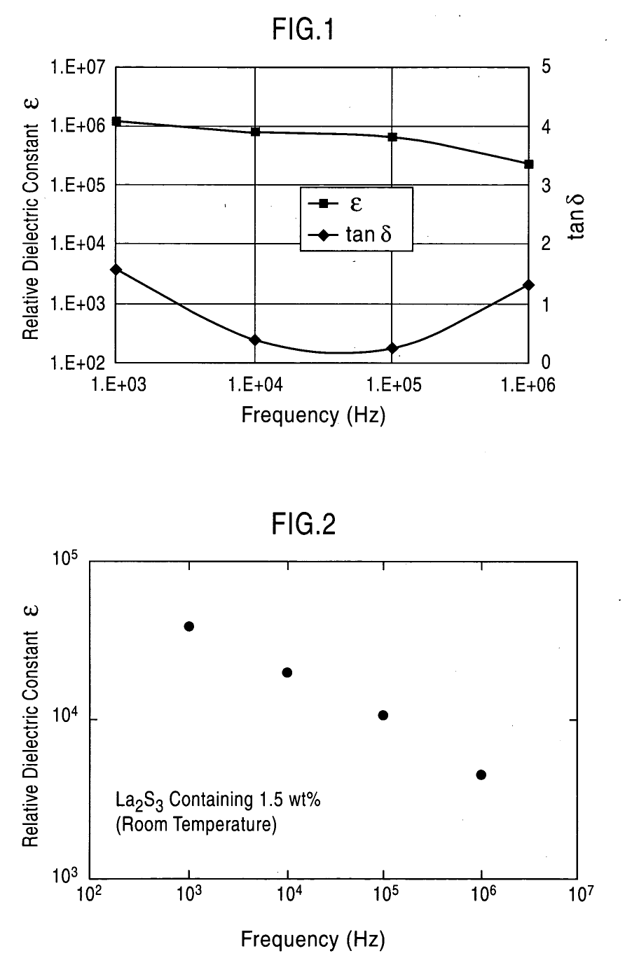

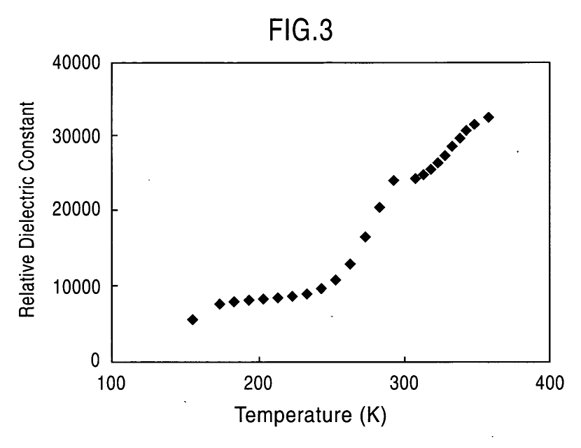

A lanthanum sulfide (La₂S₃) powder (produced by JAPAN PURE CHEMICAL CO., LTD., oxygen concentration: 1 percent by weight, particle diameter: about 0.1 to 100 μm, usage: about 4 g) was sintered by a plasma sintering method, that is, by being kept at 1,500° C. and 30 MPa for 30 minutes. The resulting sample was a disk of 15.0 mm in diameter and 4.24 mm in thickness, and was in the shape of a disk type capacitor. A gold evaporation film of 10.0 mm in diameter was used as the electrode. The capacitance of this sample as a capacitor was a few nanofarads to a few hundred nanofarads. The crystal structure of this sample was a tetragonal β type. As shown in FIG. 1, the relative dielectric constant (E) at room temperature was about 1,000,000 at a frequency of 1 kHz, and tanδ was about 1.6.

### EXAMPLE 2

A sample in which 1.5 percent by weight of platinum powder had been added to a lanthanum sulfide (La₂S₃) powder was sintered by a hot press method, that is, by being kept at 1,500° C. and 20 MPa for 10 minutes. The resulting sample was a disk of 15.0 mm in diameter and about 4 mm in thickness. A silver paste was applied all over the top and bottom surfaces of electrodes to be used. The structure of this sample was a tetragonal β type. As shown in FIG. 2, the relative dielectric constant (ε) of this sample at room temperature was about 40,000 at a frequency of 1 kHz, and was decreased with increases in frequency, so that the relative dielectric constant was about 4,000 at 1,000 kHz. FIG. 3 shows the relationship between the relative dielectric constant (ε) at an applied frequency of 1 kHz and the measurement temperature (K). The value of the relative dielectric constant was increased with increases in temperature from about 5,000 at about 160 K to 34,000 at about 370 K.

### EXAMPLE 3

A praseodymium sulfide (Pr₂S₃) powder was sintered by a plasma sintering method, that is, by being kept at 1,500° C. and 30 MPa for 10 minutes. The crystal structure of the resulting sample was a tetragonal β type. The relative dielectric constant of this sample was about 140,000 at room temperature and a frequency of 70 kHz.

### COMPARATIVE EXAMPLE 1

With respect to samarium belonging to lanthanoid series, a samarium sulfide (Sm₂S₃) powder was sintered by a plasma sintering method, that is, by being kept at 1,250° C. and 30 MPa for 10 minutes. The crystal structure of the resulting sample was a cubic γ type. The relative dielectric constant of this sample was about 40 at room temperature and a frequency within the range of 1 kHz to 10 MHz.

### Industrial Applicability

The need for substances having high dielectric constants has been intensified with miniaturization of electric circuits. A material having a high dielectric constant is required to produce a small capacitor having high capacitance. The tetragonal-structure rare-earth sulfide provided by the present invention has a very high dielectric constant and, therefore, is used in the field of electronics. When a dielectric having a high dielectric constant is provided, a high-capacitance capacitor can be produced in spite of being small. Consequently, microcircuits can be designed easily.

1. A dielectric material comprising a sintered body of rare-earth sulfide powder, the rare-earth sulfide powder having a crystal structure of tetragonal β type, a chemical composition represented by Ln₂S₃ (where Ln represents a rare-earth metal), a frequency domain within the range of 0.5 kHz to 1,000 kHz, and a value of relative dielectric constant of more than 1,000 at room temperature.

2. The dielectric material according to claim 1, wherein the rare earth comprises at least one of lanthanum (La), praseodymium (Pr), cerium (Ce), and neodymium (Nd).

3. The dielectric material according to claim 1 wherein platinum is added to the rare-earth sulfide powder to prevent a crystal structure of β-type sesquisulfide from being inverted to γ type at a high temperature.

4. The dielectric material according to claim 1 wherein the dielectric material is included in a capacitor.
